(19) United States
(12) Patent Application Publication
(10) Pub. No.: US 2012/0068212 A1
(43) Pub. Date: Mar. 22, 2012

(54) LIGHT-EMITTING DEVICE

(75) Inventor: Satoshi Komoto, Fukuoka-ken (JP)

(73) Assignee: KABUSHIKI KAISHA TOSHIBA, Tokyo (JP)

(21) Appl. No.: 13/052,253

(22) Filed: Mar. 21, 2011

(30) Foreign Application Priority Data
Sep. 21, 2010 (JP) 2010-211166

(51) Int. Cl. H01L 33/54; H01L 33/60

(52) U.S. Cl. 257/98; 257/E33.072; 257/E33.059

(57) ABSTRACT

According to one embodiment, a light emitting device includes a light emitting element, a light reflector and a sealing resin layer. The light emitting element has a first major surface and a side surface and has an optical axis of emitted light perpendicular to the first major surface. The light reflector has a light reflecting surface capable of reflecting emission light from the side surface of the light emitting element. The sealing resin layer covers the light emitting element and the light reflecting surface, and includes a first curved surface having a vertex on the optical axis and being convex toward light emitting side and an envelope surface generated by moving a second curved surface. The second curved surface has a vertex on a line passing through the light reflecting surface and being parallel to the optical axis and is convex toward the light emitting side.

### CROSS-REFERENCE TO RELATED APPLICATIONS

This application is based upon and claims the benefit of priority from the prior Japanese Patent Application No. 2010-211166, filed on Sep. 21, 2010; the entire contents of which are incorporated herein by reference.

### FIELD

Embodiments described herein relate generally to a light emitting device.

### BACKGROUND

A light emitting element can be provided on the bottom surface of a recess provided in the tip portion of a lead. Then, light emitted upward from the light emitting element, and light emitted laterally from the light emitting element and reflected at the beveled side surface of the recess can be converged by a lens to obtain high output.

In this case, the lens is made of e.g. a transparent resin. Shaping the tip portion of the lens into an ellipsoid facilitates converging light.

If the tip portion of the ellipsoid is located on the optical axis of the emission light, the light reflected upward at the beveled side surface of the recess is refracted by the curved surface of the ellipsoid and emitted outside. Hence, the converging direction of the directly emitted light around the optical axis is different from the converging direction of the reflection light. This makes the light converging effect insufficient.

### BRIEF DESCRIPTION OF THE DRAWINGS

FIG. 1A is a schematic plan view of a light emitting device according to a first embodiment, FIG. 1B is a schematic sectional view taken along line A-A, and FIG. 1C is a graph of the light intensity distribution thereof;

FIG. 2A is a schematic sectional view of a light emitting device according to a comparative example, and FIG. 2B is a graph of the light intensity distribution thereof;

FIG. 3A is a schematic plan view of a light emitting device according to a variation of the first embodiment, and FIG. 3B is a schematic sectional view taken along line B-B;

FIG. 4A is a schematic plan view of a light emitting device according to a second embodiment, and FIG. 4B is a schematic sectional view taken along line C-C;

FIG. 5A is a schematic plan view of a light emitting device according to a third embodiment, and FIG. 5B is a schematic sectional view taken along line D-D;

FIG. 6A is a schematic plan view of a light emitting device according to a variation of the third embodiment, and FIG. 6B is a schematic sectional view taken along line D-D;

FIG. 7A is a schematic plan view of a light emitting device according to a fourth embodiment, and FIG. 7B is a schematic sectional view taken along line E-E; and

FIG. 8 is a schematic perspective view of a light emitting device according to a fifth embodiment.

### DETAILED DESCRIPTION

In general, according to one embodiment, a light emitting device includes a light emitting element, a light reflector and a sealing resin layer. The light emitting element has a first major surface and a side surface and has an optical axis of emitted light perpendicular to the first major surface. The light reflector has a light reflecting surface capable of reflecting emission light from the side surface of the light emitting element. The sealing resin layer covers the light emitting element and the light reflecting surface, and includes a first curved surface having a vertex on the optical axis and being convex toward light emitting side and an envelope surface generated by moving a second curved surface. The second curved surface has a vertex on a line parallel to the optical axis and is convex toward the light emitting side. The second curved surface is moved under a condition that the line passes through the light reflecting surface.

Various embodiments will be described hereinafter with reference to the accompanying drawings.

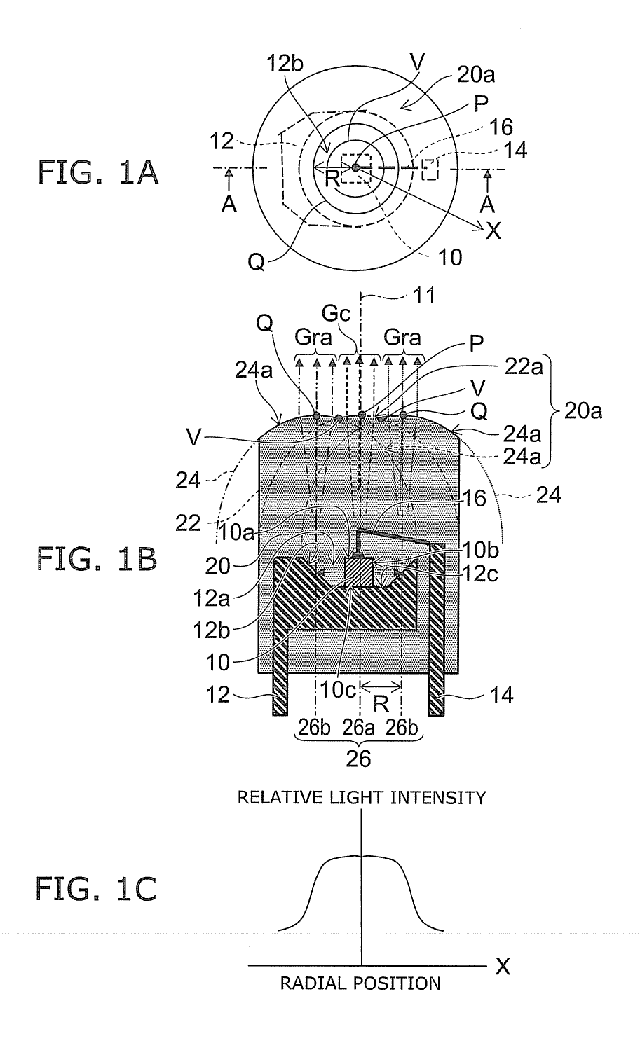

FIG. 1A is a schematic plan view of a light emitting device according to a first embodiment. FIG. 1B is a schematic sectional view taken along line A-A. FIG. 1C is a graph of the light intensity distribution thereof.

The light emitting device includes a light emitting element 10 including a semiconductor stacked body, a light reflector, and a sealing resin layer 20. The light emitting element 10 has a first major surface 10a and a side surface 10b, and has an optical axis 11 of directly emitted light Gc perpendicular to the first major surface 10a. The light reflecting surface 12b of the light reflector reflects emission light from the side surface 10b of the light emitting element 10 so that reflection light Gra is emitted upward.

The sealing resin layer 20 covers the light emitting element 10 and the light reflecting surface 12b. The sealing resin layer 20 includes a first curved surface 22 having a vertex P on the optical axis 11 and being convex toward the light emitting side, and an envelope surface 24a. The envelope surface 24a is generated as follows. A second curved surface 24 is defined as a surface which has a vertex Q on a line passing through the light reflecting surface 12b and being parallel to the optical axis 11 and is convex toward the light emitting side. The envelope surface 24a is generated by moving the second curved surface 24 under the condition that the line passing through the vertex Q passes through the light reflecting surface 12b.

The light reflector includes the sidewall of a recess 12a provided in a lead frame made of a metal. The light reflecting surface 12b thereof is the surface of the sidewall of the recess 12a surrounding the side surface 10b of the light emitting element 10. In this case, the surface of the sidewall can be provided with a metal such as silver having high reflectance in the wavelength range of the emission light. Then, the light extraction efficiency can be increased.

The light emitting device further includes a first lead 12, a second lead 14, and a bonding wire 16. The recess 12a is provided in the tip portion of the first lead 12. The recess 12a has a bottom surface 12c and a light reflecting surface 12b. The second surface 10c of the light emitting element 10 is bonded to the bottom surface 12c with metal solder or adhesive. One electrode provided on the first major surface 10a of the light emitting element 10 is connected to the second lead 14 by the bonding wire 16. As shown in FIG. 1B, the upper end of the recess 12a can be shaped like a circle as viewed from above. The shape of the upper end is not limited to a circle, but may be a rectangle, polygon, or ellipse.

The semiconductor stacked body including a light emitting layer can be made of InGaAlP-based materials represented by Inₓ(Ga_{y}Al_{1-y})₁₋ₓP (0≦x≦1, 0≦y≦1), AlGaAs-based materials represented by AlₓGa₁₋ₓAs (0≦x≦1), or InGaAlN-based materials represented by InₓGa_{y}Al_{1-x-y}N (0≦x≦1, 0≦y≦1, x+y≦1). By using these materials, emission light in the wavelength range from ultraviolet to infrared can be obtained. If the semiconductor stacked body is provided on a translucent substrate, the emission light can be emitted from the side surface of the translucent substrate, and the emission light from the side surface can be increased. In the case where an InGaAlN-based semiconductor stacked body is provided on a conductive GaN substrate, the second surface 10c side of the light emitting element 10 can be used as an electrode. In the case where an InGaAlN-based semiconductor stacked body is provided on a sapphire substrate, the two electrodes of the light emitting element are provided on the first surface 10a side, and the emission light can be emitted from the side surface 10b of the light emitting element 10.

If the light emitting element includes a translucent GaP substrate and an InGaAlP-based stacked body provided thereon, light emitted from the side surface can be increased. The emission light from the light emitting layer made of an InGaAlP-based material includes light Gc directed upward and light Gra directed laterally, reflected at the light reflecting surface 12b of the recess 12a, and directed upward. Also in the case where the light emitting element includes a translucent substrate made of sapphire, GaN, and SiC and an InGaAlN-based stacked body provided thereon, light emitted form the side surface can be increased.

The sealing resin layer 20 made of a transparent resin covers the light emitting element 10 and the light reflecting surface 12b. The transparent resin can be silicone or epoxy. Use of silicone can suppress discoloration of the resin even if the emission wavelength is in the range below blue light.

The term “transparent resin” used herein refers to a resin translucent to emission light from the light emitting element. Here, the transmittance does not necessarily need to be 100%. The “transparent resin” includes any resin having nonzero transmittance.

The first curved surface 22 can be e.g. part of a first ellipsoidal surface having a vertex P on a central axis 26a coinciding with the optical axis 11. Here, the first curved surface 22 may be a spheroidal surface.

Furthermore, the second curved surface 24 can be e.g. part of a second ellipsoidal surface having a vertex Q on a line being parallel to the optical axis 11 and passing through the light reflecting surface 12b. A circumscribed envelope surface 24a is generated by rotating the second curved surface 24 on a circle with radius R about the optical axis 11. The light emitting surface 20a of the sealing resin layer 20 includes the ellipsoidal surface 22 and the circumscribed envelope surface 24a. As shown in FIG. 1A, the trajectory of the vertex Q of the second curved surface 24 is a circle. A valley-like depression V is formed between the vertex P of the ellipsoidal surface 22 and the trajectory of the vertex Q. Here, the slope of the depression V may be continuous. For instance, the vertex Q can be made lower than the vertex P so that the first curved surface 22 smoothly turns into the second curved surface 24. Then, the curve V does not appear in a plan view.

The trajectory of the vertex Q may also be an ellipse.

The ellipsoidal surface 22 can converge the directly emitted light Gc diverging upward from the light emitting layer. On the other hand, the reflection light Gra reflected at the light reflecting surface 12b and directed upward is converged by the circumscribed envelope surface 24a, and the divergence thereof is suppressed. Thus, the converging directions of the directly emitted light Gc and the reflection light Gra can be made parallel to each other.

FIG. 1C is a graph of the light intensity distribution.

The vertical axis represents relative light intensity, and the horizontal axis represents the radial position X from the optical axis 11. The directly emitted light Gc travels along the central axis 26a, and the reflection light Gra travels along the central axis 26b. Thus, the light intensity distribution can be made uniform with respect to the radial position X. Furthermore, the directly emitted light beams Gc can be made parallel to each other by the ellipsoidal surface 22, and the reflection light beams Gra can be made parallel to each other by the circumscribed envelope surface 24a. Then, the light intensity distribution can be made more uniform. The shape of the ellipsoidal surface 22 and the circumscribed envelope surface 24a can be determined by the ray tracing method and by experiments.

The first curved surface 22 and the circumscribed envelope surface 24a only need to include a convex portion acting as a lens, and the cross-sectional shape thereof is not limited to an ellipse. In FIGS. 1A and 1B, the light reflecting surface 12b is a single surface. However, alternatively, a plurality of light reflecting surfaces may be provided using a plurality of envelope surfaces corresponding thereto. For instance, the lead may be provided with two light reflecting surfaces having two height levels.

The first curved surface 22 and the circumscribed envelope surface 24a can be easily formed by the casting or transfer molding process in which a transparent resin is poured into a mold, cured by heating or ultraviolet irradiation, and then released.

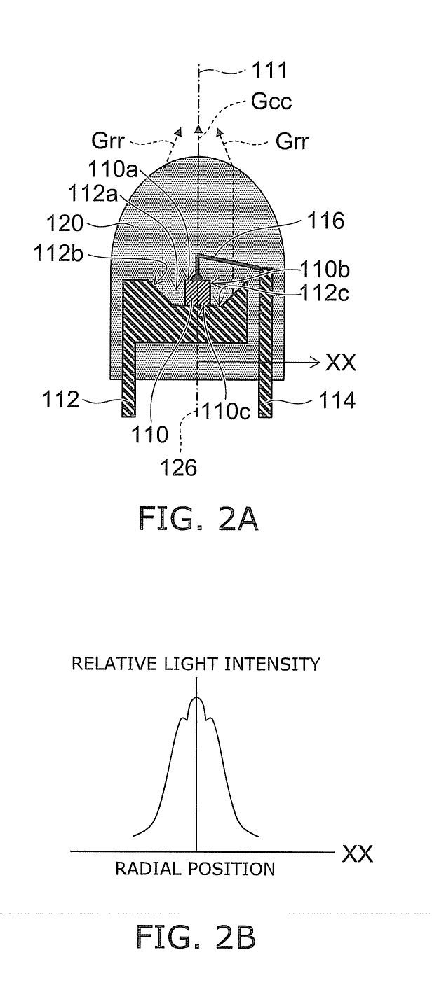

FIG. 2A is a schematic sectional view of a light emitting device according to a comparative example. FIG. 2B is a graph of the light intensity distribution thereof.

The light emitting device includes a light emitting element 110 including a semiconductor stacked body, a first lead 112, a second lead 114, a bonding wire 116, and a sealing resin layer 120.

A recess 112a is provided in the tip portion of the first lead 112. The recess 112a has a bottom surface 112c and a light reflecting surface 112b. The second surface 110c of the light emitting element 110 is bonded to the bottom surface 112c with metal solder or adhesive. One electrode of the light emitting element 110 is connected to the second lead 114 by the bonding wire 116.

The light emitting surface of the sealing resin layer 120 is an ellipsoidal surface having a central axis 126 coinciding with the optical axis 111 of the emission light, and has a lens effect. The lens suppresses divergence of the directly emitted light Gcc from the upper surface 110a of the light emitting element 110. On the other hand, the reflection light Grr from the light reflecting surface 112b of the lead 112 surrounding the light emitting element 110 is refracted by the same ellipsoidal surface above the light reflecting surface 112b. Hence, the reflection light Grr travels in a direction different from the traveling direction of the directly emitted light Gcc.

FIG. 2B is a graph of the light intensity distribution in the comparative example.

The vertical axis represents relative light intensity, and the horizontal axis represents the radial position XX. The reflection light Grr refracted by the ellipsoidal surface may concentrate on a specific radial position of the radial position XX to form a sub-peak of light intensity. Furthermore, if the refracted reflection light Grr is excessively distanced from the optical axis 111, it is difficult to converge the reflection light Grr. Thus, the light extraction efficiency decreases.

In contrast, in the first embodiment, the converging directions of the directly emitted light Gc and the reflection light Gra are made parallel to each other. This facilitates increasing the light extraction efficiency and making the light intensity distribution uniform.

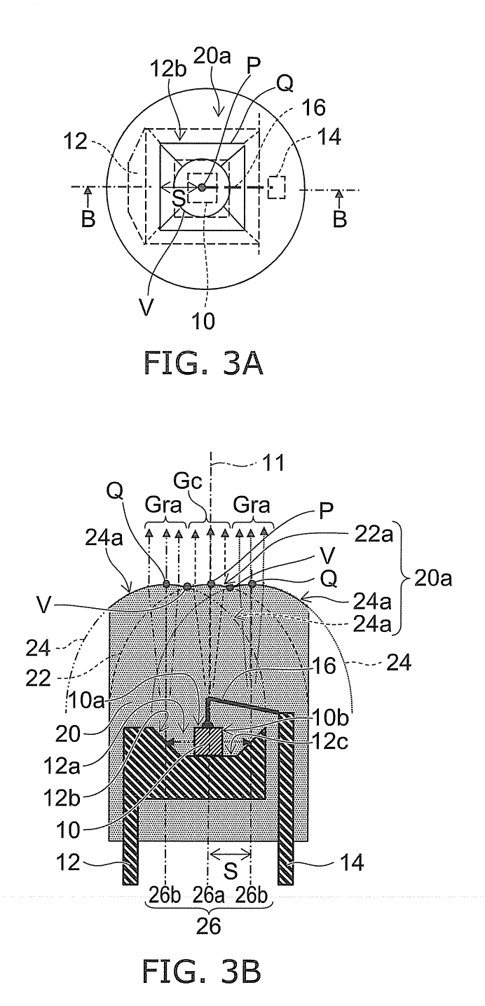

FIG. 3A is a schematic plan view of a light emitting device according to a variation of the first embodiment. FIG. 3B is a schematic sectional view taken along line B-B.

In the variation, the trajectory of the vertex Q of the second curved surface 24 forms the four sides of a rectangle as shown in FIG. 3A. In the case where the rectangle is a square, the distance between the vertex Q and the optical axis 11 is denoted by S, for instance. The light emitting surface 20a includes an ellipsoidal surface 22 and a circumscribed envelope surface 24a. The ellipsoidal surface 22 has a central axis 26a coinciding with the optical axis 11 of the directly emitted light Gc from the light emitting element 10. The light emitting surface 20a acts as a light converging lens.

A valley-like depression V is formed between the vertex P, which is the vertex of the ellipsoidal surface 22, and the rectangular trajectory of the vertex Q, which is also the vertex of the circumscribed envelope surface 24a.

The ellipsoidal surface 22 can converge the directly emitted light Gc diverging upward from the light emitting layer. The reflection light Gra reflected at the light reflecting surface 12b of the recess 12a and directed upward is converged by the circumscribed envelope surface 24a, and the divergence thereof is suppressed. Thus, the converging directions of the directly emitted light Gc and the reflection light Gra are made parallel to each other. This facilitates increasing the light extraction efficiency and making the light intensity distribution uniform.

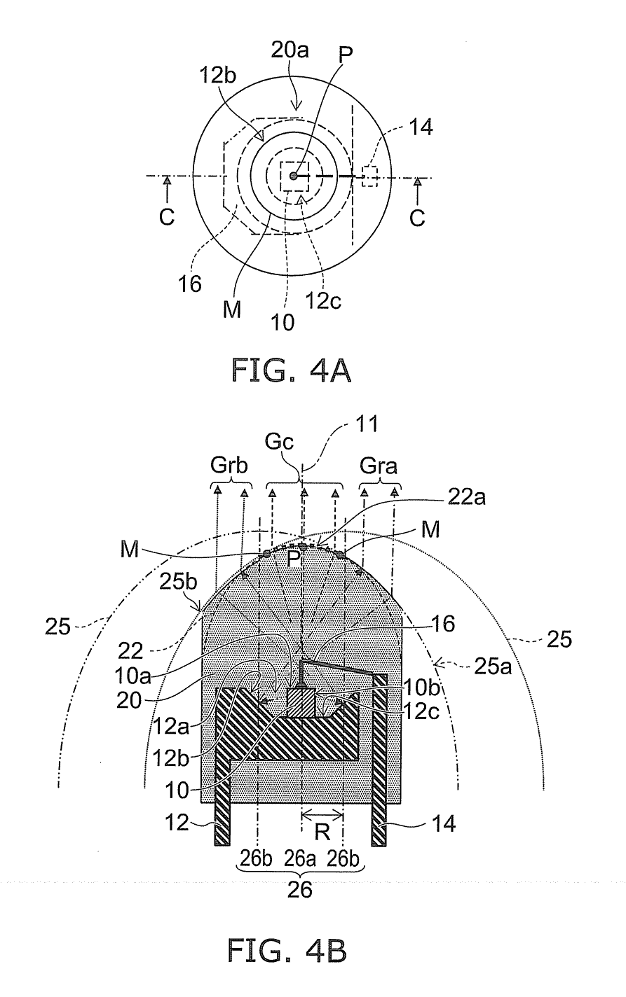

FIG. 4A is a schematic plan view of a light emitting device according to a second embodiment. FIG. 4B is a schematic sectional view taken along line C-C.

In FIGS. 4A and 4B, the light emitting surface 20a includes an ellipsoidal surface 22 having a central axis 26a coinciding with the optical axis 11 of the directly emitted light Gc from the light emitting element 10, and an inscribed envelope surface 25a. The inscribed envelope surface 25a is generated as follows. A second curved surface 25 is defined as a surface which has a vertex Q on a central axis 26b, which is a line being parallel to the optical axis 11 and passing through the light reflecting surface 12b. The inscribed envelope surface 25a is generated by moving the second curved surface 25 under the condition that the central axis 26b passes through the light reflecting surface 12b.

As shown in FIG. 4A, the central axis 26a of the first curved surface 22, which is an ellipse having a vertex P, coincides with the optical axis 11. The curvature changes on a circle M, which represents the boundary between the ellipsoidal surface 22 and the inscribed envelope surface 25a, 25b.

The ellipsoidal surface 22 converges the directly emitted light Gc diverging upward from the light emitting layer, and suppresses divergence of the directly emitted light Gc. The reflection light Gra (dot-dashed line) reflected at the light reflecting surface 12b of the recess 12a and directed obliquely upward is refracted and converged by the inscribed envelope surface 25a. The reflection light Grb (dotted line) reflected at the light reflecting surface 12b of the recess 12a and directed obliquely upward is refracted and converged by the inscribed envelope surface 25b. Thus, the converging directions of the directly emitted light Gc and the reflection light Gra, Grb can be made relatively parallel to each other.

Furthermore, the directly emitted light beams Gc can be made parallel to each other by the ellipsoidal surface 22, and the reflection light beams Gra can be made parallel to each other by the inscribed envelope surface 25a, 25b. Then, the light intensity distribution can be made more uniform. This facilitates increasing the light extraction efficiency and making the light intensity distribution uniform.

The second embodiment includes more downward components in the reflection light Gra than the first embodiment shown in FIGS. 1A to 1C. In this case, the reflection light Gra can be reflected in the direction crossing the optical axis 11 and refracted by the envelope surface 25a. Then, the converging direction thereof can be made close to the converging direction of the directly emitted light Gc more easily. It is also possible to select one of the circumscribed envelope surface and the inscribed envelope surface depending on the required directional characteristics (such as divergence of light and suppression of local peaks).

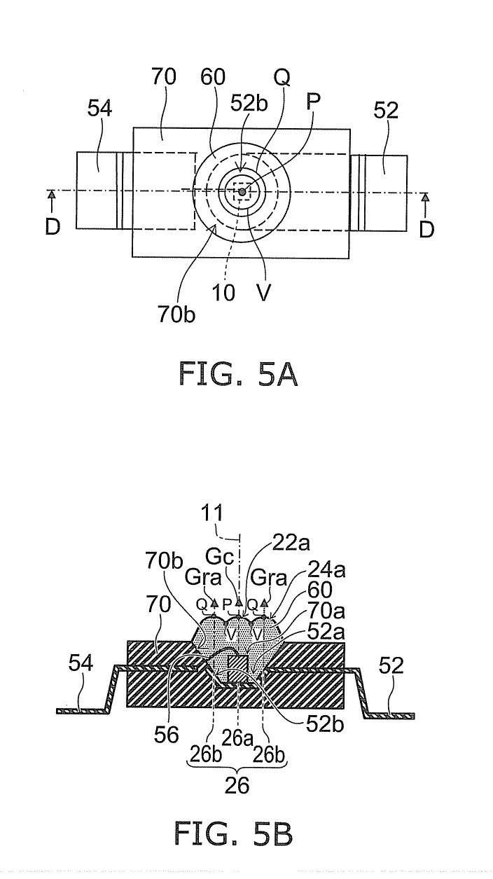

FIG. 5A is a schematic plan view of a light emitting device according to a third embodiment. FIG. 5B is a schematic sectional view taken along line D-D.

The light emitting device includes a light emitting element 10 including a semiconductor stacked body, a first lead 52, a second lead 54, a bonding wire 56, a molded body 70 made of e.g. a thermoplastic resin, and a sealing resin layer 60.

The first lead 52 and the second lead 54 extend in a plane orthogonal to the optical axis 11. A recess 52a is provided in the tip portion of the first lead 52. The recess 52a has a bottom surface and a beveled light reflecting surface 52b. The light emitting element 10 is bonded to the bottom surface with metal solder or adhesive. One electrode provided on the first major surface of the light emitting element 10 is connected to the second lead 54 by the bonding wire 56.

The first lead 52 and the second lead 54 are projected in opposite directions from the molded body 70 and further bent to facilitate mounting on a circuit board. Such a structure can be called the surface mounted device (SMD) type.

The molded body 70 includes a light reflecting surface 70b having generally the same slope as the light reflecting surface 52b provided on the first lead 52. The light reflector is the sidewall of the recess 70a provided in the molded body 70. The light reflecting surface 70b is the surface of the sidewall surrounding the side surface of the light emitting element 10. In this case, the light reflecting surface 70b can be e.g. a surface of the sidewall provided by injection molding using a resin containing a reflective filler. Here, the light reflecting surface may not be provided on the first lead 52.

The first curved surface 22 is part of an ellipsoidal surface. The first curved surface 22 has a vertex P on a central axis 26a coinciding with the optical axis 11 of the emission light from the light emitting element 10. The second curved surface 24 is an ellipsoidal surface. The second curved surface 24 has a vertex Q on a central axis 26b, which is a line being parallel to the optical axis 11 and passing through the light reflecting surface 12b, 70b. A circumscribed envelope surface 24a is generated by moving the second curved surface 24 on a circle about the optical axis 11 under the condition that the central axis 26b passes through the light reflecting surface 12b, 70b. As a result, the light emitting surface of the sealing resin layer 60 includes the ellipsoidal surface 22 and the circumscribed envelope surface 24a. As shown in FIG. 5A, a valley-like depression V is formed between the vertex P of the ellipsoidal surface 22 and the circular trajectory of the vertex Q of the circumscribed envelope surface 24a.

The ellipsoidal surface 22 can converge the emission light Gc diverging upward from the light emitting layer. On the other hand, the reflection light Gra reflected at the light reflecting surface 12b and directed upward is converged by the circumscribed envelope surface 24a, and the divergence thereof is suppressed. Thus, the converging directions of the directly emitted light Gc and the reflection light Gra can be made relatively parallel to each other. This facilitates increasing the light extraction efficiency and making the light intensity distribution uniform.

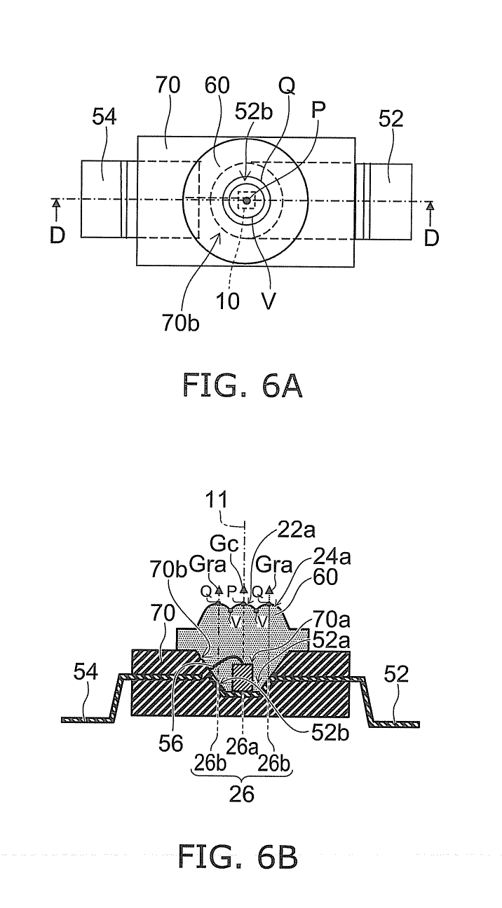

FIG. 6A is a schematic plan view of a light emitting device according to a variation of the third embodiment. FIG. 6B is a schematic sectional view taken along line D-D.

The sealing resin layer 60 can be provided so as to be larger than the recess 70a of the molded body 70 and cover part of the upper surface of the molded body 70. Thus, enlarging the size of the lens further facilitates increasing the light extraction efficiency and making the light intensity distribution uniform.

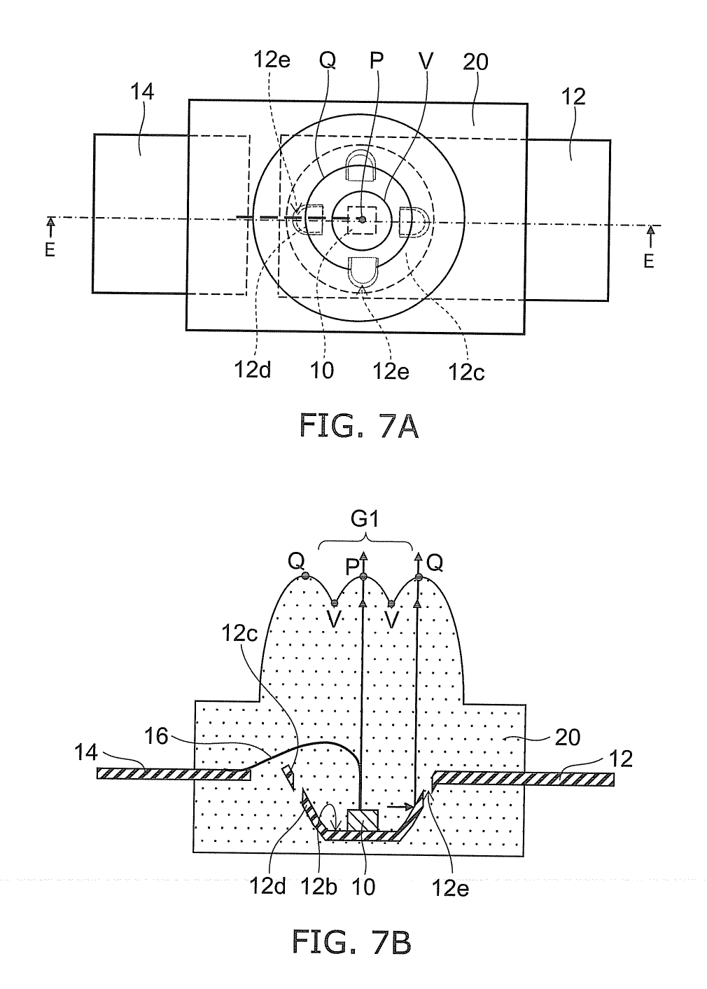

FIG. 7A is a schematic plan view of a light emitting device according to a fourth embodiment. FIG. 7B is a schematic sectional view taken along line E-E.

The SMD type light emitting device includes a light emitting element 10 including a semiconductor stacked body, a first lead 12, a second lead 14, a bonding wire 16, and a sealing resin layer 20.

A recess 12a is provided in the tip portion of the first lead 12. The recess 12a has a bottom surface 12b, a light reflecting surface 12c, and a bent portion 12d. The light emitting element 10 is bonded to the bottom surface 12b with metal solder or adhesive. One electrode provided on the first major surface of the light emitting element 10 is connected to the second lead 14 by the bonding wire 16. Furthermore, the bent portion 12d bent upward leaves behind a notch 12e. The bent portion 12d allows the lateral light emitted from the light emitting element 10 to be reflected upward, and increases the adhesiveness between the sealing resin layer 20 and the first lead 12.

The upper surface of the sealing resin layer 20 is provided with the first curved surface 22 and the circumscribed envelope surface 24a of the second curved surface 24. Thus, the light converging directions of the directly emitted light and the reflection light can be made relatively parallel to each other. This facilitates increasing the light extraction efficiency and making the light intensity distribution uniform.

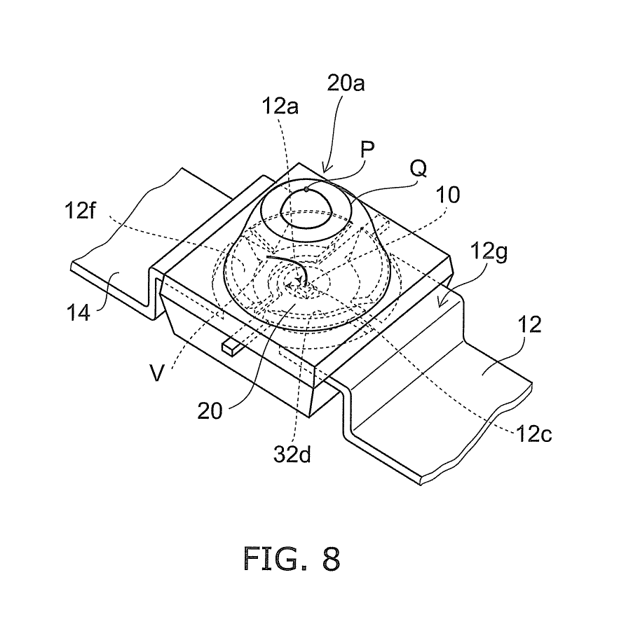

FIG. 8 is a schematic perspective view of a light emitting device according to a fifth embodiment.

A recess 12a is provided below the major surface 12g of the first lead 12. A bent portion 12f bent upward is provided above the major surface 12g. The bent portion 12f can reflect the emission light and increase the light extraction efficiency.

The first curved surface is an ellipsoidal surface. The first curved surface has a vertex P on the optical axis of the emission light from the light emitting element 10. The second curved surface has a vertex Q on a line being parallel to the optical axis and passing through the bent portion 12f and the light reflecting surface 12c, which is the side surface of the recess 12a. An envelope surface of the second curved surface is generated by moving the second curved surface. The first curved surface and the envelope surface serve as a light emitting surface 20a of the sealing resin layer 20. Here, a valley-like depression V is formed between the first curved surface and the envelope surface. Thus, the converging directions of the directly emitted light and the reflection light can be made relatively parallel to each other. This facilitates increasing the light extraction efficiency and making the light intensity distribution uniform.

An ellipsoid is given by the following equation. The ellipsoidal surface is a quadratic surface.

x²/a²+y²/b²+z²/c²=1

Here, a, b, and c represent half the length of the diameter in the x-axis, y-axis, and z-axis direction, respectively.

In the first to fifth embodiment and the variations associated therewith, the sealing resin layer may be dispersed with phosphor particles. For instance, the wavelength of emission light from the light emitting element 10 can be set in the blue light range, and yellow phosphor particles can be dispersed. Then, white light can be obtained as a mixed color.

The first to fifth embodiment and the variations associated therewith provide a light emitting device in which the light converging directions of the directly emitted light from the upper surface of the light emitting element and the light emitted from the side surface of the light emitting element and reflected by the lead can be easily made relatively parallel to each other. In such a light emitting device, the light extraction efficiency can be increased, and the light intensity distribution can be made uniform. Thus, optical characteristics meeting the requirements of illumination devices and traffic signals can be easily achieved. That is, the design flexibility of the light emitting device can be enhanced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A light emitting device comprising:
a light emitting element having a first major surface and a side surface and having an optical axis of emitted light perpendicular to the first major surface;
a light reflector having a light reflecting surface capable of reflecting emission light from the side surface of the light emitting element;
a sealing resin layer covering the light emitting element and the light reflecting surface and including a first curved surface having a vertex on the optical axis and being convex toward light emitting side and an envelope surface generated by moving a second curved surface which has a vertex on a line parallel to the optical axis and is convex toward the light emitting side, the second curved surface being moved under a condition that the line passes through the light reflecting surface.

2. The device according to claim 1, wherein
the first curved surface is a part of a first ellipsoidal surface, and
the second curved surface is a part of a second ellipsoidal surface.

3. The device according to claim 1, wherein the envelope surface includes a circumscribed envelope surface of the second curved surface.

4. The device according to claim 1, wherein the envelope surface includes an inscribed envelope surface of the second curved surface.

5. The device according to claim 1, wherein trajectory of the vertex of the second curved surface is one of a circle, ellipse, rectangle, and polygon about the optical axis.

6. The device according to claim 1, wherein curvature smoothly varies between the first curved surface and the second curved surface.

7. A light emitting device comprising:
a light emitting element having a first major surface and a side surface and having an optical axis of emitted light perpendicular to the first major surface;
a lead provided with a recess in one end portion of the lead and made of a metal, a sidewall of the recess surrounding the side surface of the light emitting element and being capable of reflecting emission light from the light emitting element;
a sealing resin layer covering the light emitting element and the one end portion of the lead and including a first curved surface having a vertex on the optical axis and being convex toward light emitting side and an envelope surface generated by moving a second curved surface which has a vertex on a line parallel to the optical axis and is convex toward the light emitting side, the second curved surface being moved under a condition that the line passes through the sidewall.

8. The device according to claim 7, wherein
the first curved surface is a part of a first ellipsoidal surface, and
the second curved surface is a part of a second ellipsoidal surface.

9. The device according to claim 7, wherein the envelope surface includes a circumscribed envelope surface of the second curved surface.

10. The device according to claim 7, wherein the envelope surface includes an inscribed envelope surface of the second curved surface.

11. The device according to claim 7, wherein trajectory of the vertex of the second curved surface is one of a circle, ellipse, rectangle, and polygon about the optical axis.

12. The device according to claim 7, wherein
the lead extends in a plane orthogonal to the optical axis,
the sidewall includes a bent portion bent upward, and
the bent portion can reflect the emission light upward.

13. The device according to claim 7, wherein
the lead extends in a plane orthogonal to the optical axis and includes a bent portion bent to a side opposite to the recess with regard to the orthogonal plane, and
the bent portion can reflect the emission light upward.

14. A light emitting device comprising:
a light emitting element having a first major surface and a side surface and having an optical axis of emitted light perpendicular to the first major surface;
a lead provided with a first recess in one end portion of the lead and made of a metal, the light emitting element being provided on a bottom surface of the first recess;
a molded body provided with a second recess, the light emitting element being exposed to the second recess, a sidewall of the second recess having a slope same as a slope of a sidewall of the first recess;
a sealing resin layer covering the light emitting element, provided in the first and second recess, and including a first curved surface having a vertex on the optical axis and being convex toward light emitting side and an envelope surface generated by moving a second curved surface which has a vertex on a line parallel to the optical axis and is convex toward the light emitting side, the second curved surface being moved under a condition that the line passes through the sidewall of the first recess or the sidewall of the second recess.

15. The device according to claim 14, wherein the molded body includes a reflective filler.

16. The device according to claim 14, wherein
the first curved surface is a part of a first ellipsoidal surface, and
the second curved surface is a part of a second ellipsoidal surface.

17. The device according to claim 14, wherein the envelope surface includes a circumscribed envelope surface of the second curved surface.

18. The device according to claim 14, wherein the envelope surface includes an inscribed envelope surface of the second curved surface.

19. The device according to claim 14, wherein trajectory of the vertex of the second curved surface is one of a circle, ellipse, rectangle, and polygon about the optical axis.

20. The device according to claim 14, wherein the sealing resin layer is provided so as to be larger than the second recess and cover a part of an upper surface of the molded body.
